(19) United States
(12) Patent Application Publication
(10) Pub. No.: US 2005/0124162 A1
(43) Pub. Date: Jun. 9, 2005

(54) Fabrication method for a hard mask on a semiconductor structure

(76) Inventor: Lars Volkel, Dresden (DE)

Correspondence Address: JENKINS, WILSON & TAYLOR, P. A., 3100 TOWER BLVD, SUITE 1400, DURHAM, NC, 27707, US

(21) Appl. No.: 10/988,346

(22) Filed: Nov. 12, 2004

(30) Foreign Application Priority Data
Dec. 4, 2003 (DE) 10356668.6

(51) Int. Cl. H01L 21/4763; H01L 21/302; H01L 21/461

(52) U.S. Cl. 438/689; 438/725; 438/736

(57) ABSTRACT

The present invention provides a fabrication method for a for a hard mask on semiconductor structure having the following steps: provision of a semiconductor substrate (1); application of a hard mask layer (5) to the semiconductor substrate (1); application of a silicon-containing spin-on mask layer (13) on the hard mask layer (5); application of a photoresist mask layer (11) on the spin-on mask layer (13); photolithographic patterning of the photoresist mask layer (11); transfer of the patterning of the photoresist mask layer (11) to the silicon-containing spin-on mask layer (13) by means of a first etching method; and transfer of the patterning of the spin-on mask layer (13) to the hard mask layer (5) by means of a second etching method.

### DESCRIPTION

The present invention relates to a fabrication method for a hard mask on a semiconductor structure.

Although applicable in principle to any desired integrated circuits, the present invention and also the problem area on which it is based are explained with regard to integrated circuits in silicon technology.

Semiconductor components are essentially patterned by combination of optical exposure processes and dry etching methods. On account of ever shrinking structures, the resist mask becomes ever thinner (aspect ratio remaining the same) and no longer suffices as sole mask for the dry etching. The introduction of hard masks, for example of carbon hard masks, was the consequence.

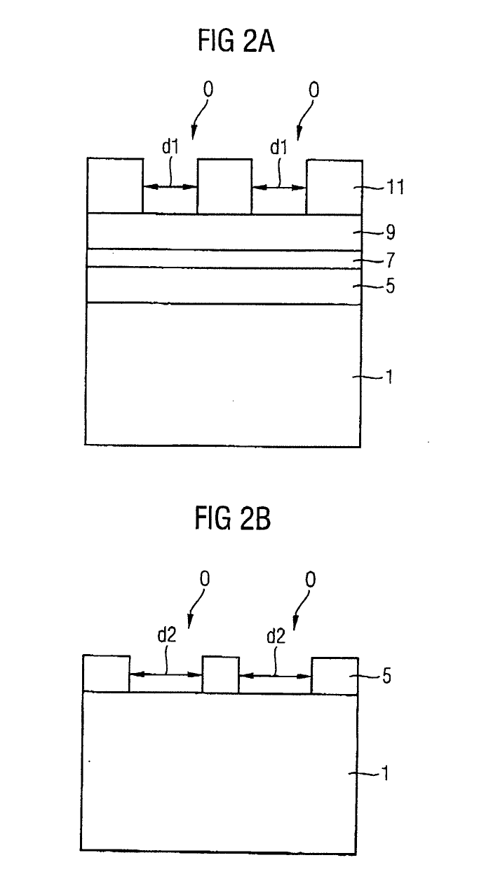

In FIG. 2a, reference symbol 1 designates a silicon semiconductor substrate, on which a carbon hard mask layer 5, an SiON mask layer 7, an organic intermediate layer (e.g. BARC layer) 9 and a patterned photoresist mask layer 11 are provided. The patterned photoresist mask layer 11 has openings O having an opening diameter d1.

The organic intermediate layer 9, e.g. an organic BARC having a thickness of more than 40 nm, between the SiON mask layer 7 and the photoresist mask layer 11 had to be introduced in order to prevent a chemical and lithographic interaction between the SiON mask layer 7 and the photoresist mask layer 11. This has led to the disadvantage that, owing to the necessity of the opening of the additional organic intermediate layer 9, an erosion of the patterned photoresist mask layer 11 occurs during plasma etching. This in turn leads to a smaller resist budget and critical dimension budget and also an increase in the line edge roughness (LER).

In the typical course of the process for fabricating a hard mask in accordance with FIGS. 2a, 2b, therefore, firstly the structure of the photoresist mask layer 11 is transferred into the organic intermediate layer 7 and the SiON layer, then the photoresist mask layer 11 is removed and then the structure is transferred further into the carbon hard mask layer 5 by means of a further plasma etching process.

In this case, FIG. 2b shows the process state after removal of the SiON mask layer 7 and the organic intermediate layer 9. The substrate 1 is then etched with the aid of the patterned carbon hard mask layer 5.

It is striking that the openings O have changed into widened openings O′ having an increased opening diameter d2. In other words, a dimensionally accurate transfer of the structure into the carbon hard mask layer 5 is not possible in the case of this customary method.

Therefore, it is an object of the present invention to provide a fabrication method for a hard mask on a semiconductor structure which is less complicated and problematic.

According to the invention, this problem is solved by means of the fabrication method specified in Claim 1.

The idea on which the present invention is based consists in replacing the SiON mask layer and the organic intermediate layer by a single corresponding layer having suitable properties. According to the invention, this single layer is a silicon-containing spin-on mask layer that is spun onto the structure exactly like a photoresist mask layer.

The procedure according to the invention enables deposition processes to be saved, namely the application of the SiON and also the application of the organic intermediate layer.

The silicon-containing spin-on material is lithographically compatible with photoresist and carbon, and an adaptation to the lithographic functionality of the photoresist is possible. Scumming does not occur, a good adhesion is achieved, and standing wave problems can also be avoided. Completely obviating the organic intermediate layer means a saving in respect of material and time expenditure. The dry etching can be made shorter since the organic intermediate layer no longer has to be perforated, which leads to a reduced resist erosion of the photoresist mask layer. Associated with this are better control of the critical dimension, the capability of obtaining smaller aspect ratios, a reduced line edge roughness and less variation of the critical dimension.

The use of the silicon-containing spin-on mask layer makes it possible to realize different hard mask concepts in conjunction with lower complexity, lower resist thickness and better performance in order to realize future shrinks.

Advantageous developments and improvements of the subject matter of the invention are found in the subclaims.

In accordance with one preferred development, the patterned photoresist mask layer is removed after the transfer of the patterning to the silicon-containing spin-on mask layer.

In accordance with a further preferred development, the silicon-containing spin-on mask layer is removed after the transfer of the patterning to the hard mask layer.

In accordance with a further preferred development, the hard mask layer is a carbon hard mask layer.

In accordance with a further preferred development, the silicon-containing spin-on mask layer is a spin-on glass layer.

In accordance with a further preferred development, the silicon-containing spin-on mask layer is a silicon-containing organic layer.

In accordance with a further preferred development, the silicon-containing organic layer has a proportion of silicon of 5 to 15% silicon, preferably 10% silicon.

In accordance with a further preferred development, the silicon-containing spin-on mask layer is subjected to heat treatment after application at a temperature of at most 300° C.

An exemplary embodiment of the invention is illustrated in the drawings and explained in more detail in the description below.

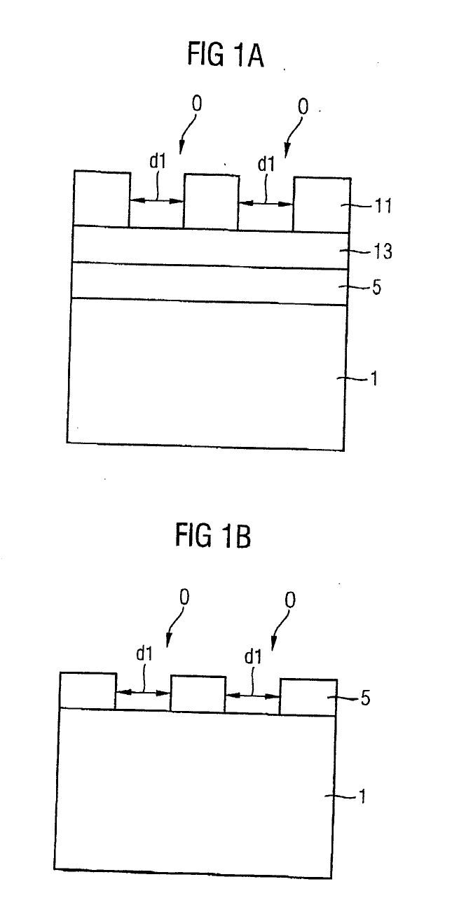

FIGS. 1a, b show diagrammatic illustrations of successive method stages of a fabrication method for a hard mask on a semiconductor structure as an embodiment of the present invention; and

FIG. 2 shows problems which occur during a customary fabrication method for a hard mask on a semiconductor structure.

In the figures, identical reference symbols designate identical or functionally identical constituent parts.

In FIG. 1a, as in FIG. 2a, a carbon hard mask layer 5 is applied on a silicon semiconductor substrate. In contrast to FIG. 2a, however, a silicon-containing spin-on mask layer 13 in the form of a spin-on glass mask layer is situated directly above the carbon hard mask layer 5. The spin-on glass mask layer is spun onto the structure like a photoresist and subsequently cured in a heat treatment step at temperatures of typically less than 300° C., the organic solvent contained being virtually completely evaporated.

Afterward, the photoresist mask layer 11 is applied and patterned.

In order to arrive at the process state in accordance with FIG. 1b from the process state in accordance with FIG. 1a, firstly the structure of the photoresist mask layer 11 is transferred into the spin-on glass mask layer 13 by means of a first plasma etching method. The photoresist mask layer 11 is then removed. Next, a second etching step is effected, which is likewise a dry etching step in this example, in order to transfer the structure further into the carbon hard mask layer 5.

Finally, the spin-on glass mask layer 13 is removed, which results in the process state in accordance with FIG. 1b.

In contrast to the known example in accordance with FIG. 2b, the method for fabricating a hard mask layer in accordance with the exemplary embodiment of the invention is dimensionally or structurally true. In other words, the openings O in the carbon hard mask layer 5 correspond to the openings O in the photoresist mask layer 11, i.e. they have the same opening diameter d1.

Although the silicon-containing spin-on mask layer was a spin-on glass mask layer in the example described, silicon-containing organic mask layers which have a silicon content of between typically 5% and 15% and in which organic constituents remain in the layer after thermal curing are also suitable for this.

Although the present invention has been described above on the basis of a preferred exemplary embodiment, it is not restricted thereto, but rather can be modified in diverse ways.

In particular, the invention can be applied in principle to any desired semiconductor structures.

1. Fabrication method for a hard mask on semiconductor structure having the following steps:
a) providing of a semiconductor substrate;
b) applying of a hard mask layer to the semiconductor substrate;
c) applying of a silicon-containing spin-on mask layer on the hard mask layer;
d) applying of a photoresist mask layer on the spin-on mask layer;
e) patterning photolithographic of the photoresist mask layer;
f) transferring of the patterning of the photoresist mask layer to the silicon-containing spin-on mask layer by means of a first etching method; and
g) transferring of the patterning of the spin-on mask layer to the hard mask layer by means of a second etching method.

2. Method according to claim 1, wherein the patterned photoresist mask layer is removed after the transfer of the patterning to the silicon-containing spin-on mask layer.

3. Method according to claim 1, wherein the silicon-containing spin-on mask layer is removed after the transfer of the patterning to the hard mask layer.

4. Method according to claim 1, wherein the hard mask layer is a carbon hard mask layer.

5. Method according to claim 1, wherein the silicon-containing spin-on mask layer is a spin-on glass layer.

6. Method according to claim 1, wherein the silicon-containing spin-on mask layer is a silicon-containing organic layer.

7. Method according to claim 6, wherein the silicon-containing organic layer has a proportion of silicon of 5 to 15% silicon, preferably 10% silicon.

8. Method according to claim 1, wherein the silicon-containing spin-on mask layer is subjected to heat treatment after application at a temperature of at most 300° C.
